(19) United States
(12) Patent Application Publication
(10) Pub. No.: US 2005/0242346 A1
(43) Pub. Date: Nov. 3, 2005

(54) Very low voltage, high efficiency pholed in a p-i-n structure

(76) Inventors: Stephen R. Forrest, Princeton, NJ (US); Martin Pfeiffer, Dresden (DE)

Correspondence Address: KENYON & KENYON, One Broadway, New York, NY, 10004, US

(21) Appl. No.: 11/177,812

(22) Filed: Jul. 8, 2005

Related U.S. Application Data
(62) Division of application No. 10/173,682, filed on Jun. 18, 2002.

(51) Int. Cl. H01L 29/08

(52) U.S. Cl. 257/40

(57) ABSTRACT

An organic light emitting device is provided, having a p-doped organic layer, an n-doped layer, and a phosphorescent emissive layer disposed between the p-doped and n-doped layers. Blocking layers are used to confine electrons, holes, and excitons in the emissive layer. A device having a cathode on the top is provided, as well as an “inverted” device having a cathode on the bottom.

### FIELD OF THE INVENTION

The present invention relates to organic light emitting devices, and more specifically to the use of blocking layers to increase the efficiency of such devices.

### Background

Organic light emitting devices (OLEDs), which make use of thin films that emit light when excited by electric current, are becoming an increasingly recognized technology for applications such as flat panel displays. Popular OLED configurations include double heterostructure, single heterostructure, and single layer, as described in PCT Application WO 96/19792, which is incorporated herein by reference.

Until recently, OLED devices generally relied on intrinsic semiconductor materials. The hole transport, electron transport, and emissive layers were not doped for the purpose of controlling carrier concentration. An OLED having a p-i-n structure is described in Huang et al., Low Voltage Organic Electroluminescent Devices Using pin Structures, Applied Physics Letters, Vol. 80, No. 1, pp 139-141 (2002). In particular, the OLED has a p-doped layer, an intrinsic emissive layer, and an n-doped layer. Huang also describes the use of “blocking” layers on both sides of the organic emissive layer of a p-i-n OLED.

### SUMMARY OF THE INVENTION

An organic light emitting device is provided, having a p-doped organic layer, an n-doped layer, and a phosphorescent emissive layer disposed between the p-doped and n-doped doped layers. Blocking layers are used to confine electrons, holes, and excitons in the emissive layer. A device having a cathode on the top is provided, as well as an “inverted” device having a cathode on the bottom.

### BRIEF DESCRIPTION OF THE DRAWINGS

FIG. 1 shows a p-i-n organic light emitting device having a cathode on the top of the device.

FIG. 2 shows an n-i-p organic light emitting device having a cathode on the bottom of the device.

FIG. 3 shows the I-V characteristics of devices fabricated in accordance with an embodiment of the present invention;

FIG. 4 shows the quantum efficiency-voltage characteristics of devices fabricated in accordance with an embodiment of the present invention;

FIG. 5 shows the power efficiency-current density characteristics of devices fabricated in accordance with an embodiment of the present invention;

FIG. 6 shows the quantum efficiency-luminance characteristics of devices fabricated in accordance with an embodiment of the present invention;

FIG. 7 shows the electroluminescent (EL) intensity-voltage characteristics of devices fabricated in accordance with an embodiment of the present invention;

FIG. 8 shows the EL intensity-voltage characteristics for devices fabricated in accordance with an embodiment of the present invention;

FIG. 9 shows the quantum efficiency and the power efficiency of devices fabricated in accordance with an embodiment of the present invention; and

FIG. 10 shows the transmission-wavelength characteristics for devices fabricated in accordance with an embodiment of the present invention.

### DETAILED DESCRIPTION

An OLED having a p-i-n structure has an anode, a p-doped organic layer adapted to transport holes, an intrinsic organic emissive layer, an n-doped organic layer adapted to transport electrons, and a cathode. The device is referred to as a p-i-n device because, as one moves away from the substrate, there is a p-doped layer, an intrinsic layer, and an n-doped layer, in that order. When a current is applied between the anode and cathode, holes are injected from the anode into the p-doped layer, and subsequently into the emissive layer. Electrons are injected from the cathode into the n-doped layer, and subsequently into the emissive layer. Electrons and holes may combine in the emissive layer to form an exciton, which may subsequently decay to emit light. In a theoretical 100% efficient OLED, all of the electrons and holes would combine in the emissive layer to form excitons and subsequently emit light. As used herein, the terms “doping” and “doped” refers to the addition of a second constituent to a base material, where the concentration of the second constituent may range from just over zero to almost 100%.

Embodiments of the present invention may be-used with a doped emissive layer, even though the layer is described here as intrinsic. For example, the emissive layer may be doped with dyes to control the emissive properties. At high doping levels of dyes, the conductivity may also increase.

In a fluorescent emissive material, for example Alq3, spin states associated with an exciton disallow many of the excitons from emitting light, as described in Adachi, Baldo, Thompson, and Forrest, “Nearly 100% Internal Phosphorescent Efficiency In An Organic Light Emitting Device,” J. Appl. Phys., 90 5048 (2001), which is incorporated herein by reference. In contrast, spin states allow excitons to emit light in particular classes of phosphorescent emissive materials known to the art.

In addition, electrons injected from the n-doped layer into the emissive layer may travel across the emissive layer without combining with a hole, and pass into the p-doped layer. Similarly, a hole may travel across the emissive layer without combining with an electron, and pass into the n-doped layer. Once this happens, the electrons and holes in question are not available to form a light-emitting exciton, decreasing device efficiency.

Also, there are a number of ways that an exciton may decay without emitting light. An exciton may quench on an impurity in the emissive layer. Where a p-doped layer or an n-doped layer is used, any dopant that diffuses into the emissive layer from these transport layers may quench excitons. The use of undoped buffer layers to prevent such diffusion is described in Huang at 140.

In addition, excitons may diffuse out of the emissive layer into the surrounding layers, where they will not emit light. Such diffusion is not generally a problem in fluorescent devices, because the excitons have relatively short lifetimes and diffusion lengths, on the order of 1 to 10 nanoseconds and 1 to 5 nanometers. But, in a phosphorescent material, excitons may have much longer lifetimes and diffusion lengths, on the order of 100 to 1000 nanoseconds and 50 to 200 nanometers, and such diffusion may be more significant.

Blocking layers may be used to prevent electrons and holes from leaving the emissive layer. An electron blocking layer may be disposed between the emissive layer and the p-doped layer, to prevent electrons from passing into the p-doped layer. Preferably, the energy barrier is sufficiently great that even high energy electrons have a small probability of surmounting the barrier. As a result, the energy barrier is preferably significantly higher than the thermal energy.

Similarly, a hole blocking layer may be disposed between the emissive layer and the n-doped layer, to prevent holes from passing onto the-n-doped layer. Preferably, the energy barrier is sufficiently great that even high energy holes have a small probability of surmounting the barrier. As a result, the energy barrier is preferably significantly higher than the thermal energy.

Blocking layers may also be used to prevent excitons from diffusing out of the emissive layer. An exciton, which is an electron that has been excited into the conduction band, paired with a hole located on the same organic semiconductor molecule, has an energy that is related to the band gap of the semiconductor. The exciton energy is actually less than the band gap due to Coulombic attraction of the bound electron-hole pair. A material having a particular exciton energy will block the entry of excitons from a material having a lower exciton energy.

Excitons in a material having a particular band gap (the difference between the HOMO and LUMO energy levels) generally have an energy level that is less than that of excitons in a material having a wider band gap. Accordingly, excitons generally may not diffuse from a material having a lower band gap into a material having a higher band gap, and a higher band gap material may be used to block excitons from leaving a lower band gap material.

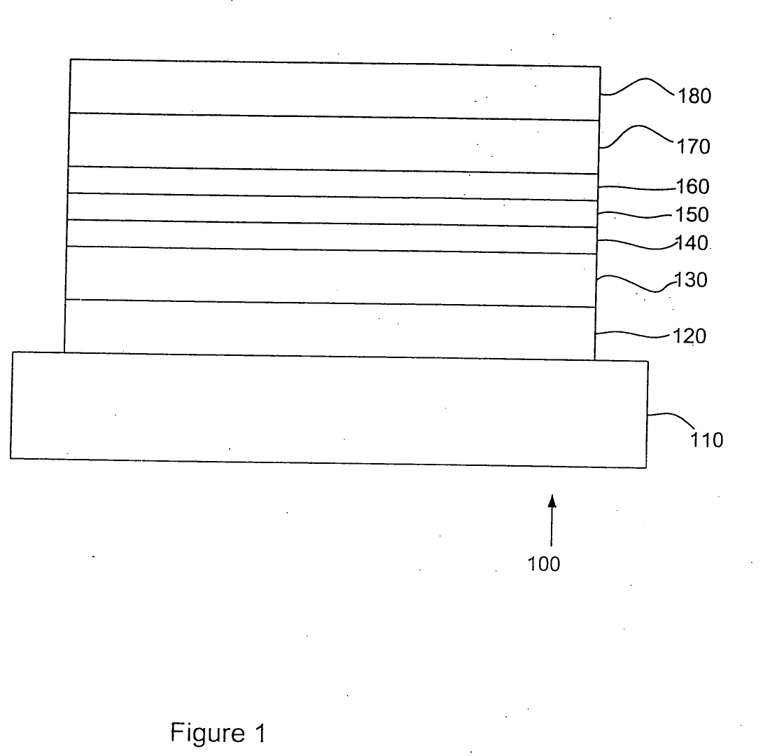

FIG. 1 shows an organic light emitting device 100. The device includes a substrate 110, an anode 120, a p-doped layer 130, a first blocking layer 140, an emissive layer 150, a second blocking layer 160, an n-doped layer 170, and a cathode 180. Because layer 130 is p-doped, emissive layer 150 is intrinsic, and layer 170 is n-doped, device 100 may be referred to as a p-i-n device. Device 100 may be fabricated by depositing the layers described, in order.

Substrate 110 and anode 120 may be any suitable material or combination of materials known to the art, such that anode 120 is adapted to inject holes into p-doped layer 130. Anode 120 and substrate 110 may be sufficiently transparent to create a bottom emitting device. A preferred substrate and anode combination, which is transparent, is commercially available ITO (anode) deposited on glass or plastic (substrate). Substrate 110 may be rigid of flexible. Preferred anode materials include conductive metal oxides and metals. A hole-injection enhancement layer may be used to increase the injection of holes from anode 120 into p-doped layer 130.

P-doped layer 130 may be a p-doped organic semiconductor material. For example, m-MTDATA:F4-TCNQ (50:1), which is m-MTDATA doped with F4-TCNQ at a molar ratio of 50:1, is a suitable p-doped organic semiconductor material for p-doped layer 130. Any of organic layers of the various embodiments may be deposited by methods known to the art, including thermal evaporation or organic vapor phase deposition (OVPD), such as described in U.S. Pat. No. 6,337,102 to Forrest et al., which is incorporated by reference in its entirety.

First blocking layer 140 may be adapted to block electrons from moving out of emissive layer 150 into first blocking layer 140. This blocking may be accomplished by using a first blocking layer 140 having a LUMO (lowest unoccupied molecular orbital) energy level that is significantly higher than the LUMO energy level of emissive layer 150. A greater difference in LUMO energy levels results in better electron blocking properties. Suitable materials for use in first blocking layer 140 are dependent upon the material of emissive layer 150.

Emissive layer 150 may be any suitable organic emissive material. Preferably, emissive layer 150 is a phosphorescent emissive material, although fluorescent emissive materials may also be used. Phosphorescent materials are preferred because of the higher luminescent efficiencies associated with such materials. Many emissive materials have resistivity that is significant, so it is also preferable to minimize the thickness of emissive layer 150, while still having a thickness sufficient to ensure a contiguous layer.

Second blocking layer 160 may be adapted to block holes from moving out of emissive layer 150 into second blocking layer 160. This blocking may be accomplished by using a second blocking layer 160 having a HOMO (highest occupied molecular orbital) energy level that significantly higher than the HOMO energy level of emissive layer 150. A greater difference in HOMO energy levels results in better hole blocking properties. Suitable materials for use in second blocking layer 160 are dependent upon the material of emissive layer 150.

N-doped layer 170 may be an n-doped organic semiconductor material. For example, BPhen*Li (1:1), which is BPhen doped with Li at a molar ratio of 1: 1, is a suitable n-doped organic semiconductor material for n-doped layer 170.

Cathode 180 may be any suitable material or combination of materials known to the art, such that cathode 180 is adapted to inject electrons into n-doped layer 170. For example, ITO, zinc-indium-tin oxide, and other materials known to the art may be used. Cathode 180 may be sufficiently transparent to create a top emitting device. Both cathode 180 and anode 120 may be transparent or partially transparent to create a transparent OLED. An electron-injection enhancement layer may be used to increase the injection of electrons from cathode 180 into n-doped layer 170.

Where emissive layer 150 is a phosphorescent material, first blocking layer 140 and second blocking layer 160 preferably have exciton energies higher than that of emissive layer 150. Generally, this may be accomplished by using materials for first blocking layer 140 and second blocking layer 160 that have wider band gaps than emissive layer 150.

Preferably, blocking layers 140 and 160 are not doped to enhance their conductivity. Doping these layers in such a manner may allow the dopant in question to diffuse into the emissive layer, where it may quench excitons and reduce device efficiency. In addition, blocking layers 140 and 160 are preferably sufficiently thick, and the process parameters are sufficiently controlled, that there is little or no diffusion of dopants from p-doped layer 130 and n-doped layer 170 into emissive layer 150. It may be desirable to enhance the stability of certain blocking layer materials, such as BPhen and BCP, by adding another constituent to these layers. Wakimoto, U.S. patent application Pub. 2001/0,043,044 at paragraph 40, and Wakimoto, U.S. patent application Pub. 2001/0,052,751 at paragraph 36, which are incorporated by reference in their entireties, describe the mixing of BCP with another constituent.

Because first and second blocking layers 140 and 160 may prevent the movement of electrons, holes, and excitons out of emissive layer 150, it may be possible to use a very thin emissive layer, on the order of 10 nm or less, and more preferably about 5 nm or less, in conjunction with the blocking layers. A thin emissive layer 150 advantageously reduces the resistance of the OLED. The use of such a thin emissive layer may not be feasible without the sue of blocking layers, because electrons, holes, and excitons might readily move out of a thin emissive layer, reducing device efficiency.

Most preferably, two blocking layers, one on either side of the emissive layer, are used to maximize the number of charge carriers and excitons trapped in the emissive layer. But, the use of a single blocking layer to prevent excitons and charge carriers from leaving one side of the emissive layer is also within the scope of the invention.

A first preferred embodiment uses the following materials and thicknesses: substrate 110 commercially available ITO coated (150 nm) substrate and anode 120:
p-doped layer 130: 50 nm m-MTDATA:F4-TCNQ (50:1)
first blocking layer 140: 10 nm Ir(ppz)3
emissive layer 150: 5 nm CBP:Ir(ppy)3 (13:1)
second blocking layer 160: 25 nm Bphen
p-doped layer 170: 35 nm BPhen*Li (1:1)
cathode 180: 100 nm Al

The quantum efficiency of the first preferred embodiment may be high for several reasons. Emissive layer 150 of this embodiment is a phosphorescent material, which results in a device having high quantum efficiency. First blocking layer 140 and second blocking layer 160 are undoped, so that there are no dopants to diffuse from those layers into emissive layer 150. First blocking layer 140 and second blocking layer 160 have higher band gaps, and higher exciton energies, than emissive layer 150. Consequently, excitons that form in emissive layer 150 may not diffuse out. In first blocking layer 140, the doping profile of F4-TCNQ in m-MTDATA may be well defined by controlled coevaporation, and the diffusion of F4-TCNQ at room temperature is minimal. Similarly, Li has a very low diffusion length in BPhen due to the closely packed structure of BPhen. As a result, there should be very little or no F4-TCNQ or Li diffusion into emissive layer 150 at room temperature, and very little or no exciton quenching due to such diffusion.

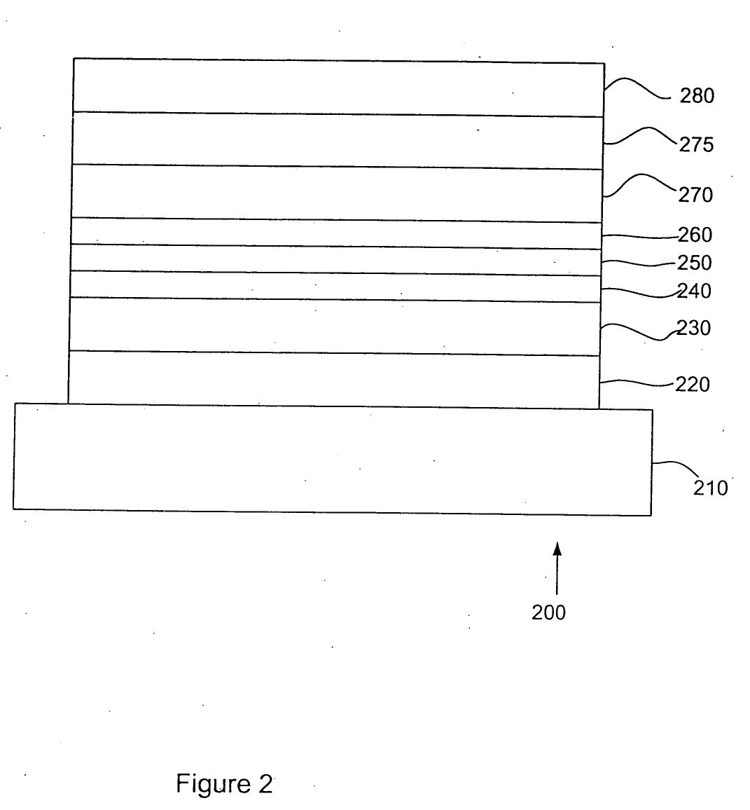

The first preferred embodiment may have a low operating voltage for several reasons. The injection of carriers into the highly doped-transport layers is efficient, such that injection enhancement layers are not necessary in this embodiment. It is believed that the tunneling of electrons through an extremely thin depletion layer may play a role in the efficient injection of electrons from Al into Li-doped BPhen. With reference to FIG. 2, holes injected from the ITO anode 120 face a low series of barriers from ITO to m-MTDATA to Ir(ppz)3 to Ir(ppy)3. Similarly, electrons injected from Al cathode 180 face a low series of barriers from Al to Li:BPhen to BPhen to Ir(ppy)3. The role of the HOMO and LUMO of CBP for carrier transport is unclear. The doped transport layers (n-doped layer 170 and p-doped layer 130) have high conductivity, and consequently low ohmic losses. The undoped layers (first blocking layer 140, emissive layer 150, and second blocking layer 160) have a low total thickness, so the relatively lower conductivity does not lead to significant ohmic losses. Some Li diffusion into the undoped BPhen may further lower the thickness of the higher conductivity undoped region. In addition, undoped BPhen has a high electron mobility. Ir(ppy)3 forms a trap in CBP for both electrons and holes, so the effective carrier mobilities are expected to be low. But, the low thickness of the CBP:Ir(ppy)3 layer mitigates this low effective mobility.

FIG. 2 shows an organic light emitting device 200. The device includes a substrate 210, a cathode 220, an n-doped layer 230, a first blocking layer 240, an emissive layer 250, a second blocking layer 260, a p-doped layer 270, and an anode 280. Because OLEDs are generally fabricated with the anode on the bottom and the cathode on the top, and the device of FIG. 2 has cathode 220 on the bottom and anode 280 on the top, the device of FIG. 2 may be referred to as an “inverted” OLED. Device 200 may be fabricated by depositing the layers described, in order.

Substrate 210 and cathode 220 may be any suitable material or combination of materials known to the art, such that cathode 220 is adapted to inject electrons into n-doped layer 230. Cathode 220 and substrate 210 may be sufficiently transparent to create a bottom emitting device. Materials similar to those described for substrate 110 may be used. An electron-injection enhancement layer may be used to increase the injection of holes from cathode 220 into n-doped layer 230.

Because cathode 220 is on the bottom of the device, device 200 is particularly suitable for use with n-type transistors fabricated on the substrate. Some particularly desirable substrates, such as amorphous silicon, may allow for the fabrication of only n-type transistors. Cathodes are best controlled by an n-type transistor, and anodes are best controlled by p-type transistors. As a result, an inverted device such as device 200 favorably allows for the fabrication of OLEDs on an amorphous silicon substrate, and for the fabrication of an active matrix display of inverted OLEDs with a common top anode on an amorphous silicon substrate.

N-doped layer 230, first blocking layer 240, emissive layer 250, and second blocking layer 260 may be made of materials similar to n-doped layer 170, second blocking layer 160, emissive layer 150, and first blocking layer 140, respectively, of device 100, and have similar considerations.

P-doped layer 270 may be a p-doped organic semiconductor material, and may be made of materials suitable for use in p-doped layer 130 of device 100. But, because device 200 has a sputtered top electrode, it is desirable to protect emissive layer 250 from damage during the deposition of top electrode 280. Consequently, it may be desirable to use a thick p-doped layer 270 to contribute to such protection.

Buffer layer 275 may be a p-doped organic semiconductor material, and may be made of any suitable material that transports holes from anode 280 to p-doped layer 270, and provides protection to the underlying organic layer during the deposition of anode 280. CuPc is known as a suitable protective buffer layer material, and CuPc:F4-TCNQ (50:1) is a suitable material for buffer layer 275. If p-doped layer 270 provides adequate protection to the underlying organic layers, and is able to form a good interface with sputter deposited ITO, buffer layer 275 may not be necessary.

Anode 280 may be any suitable material or combination of materials known to the art, such that anode 280 is adapted to inject electrons into n-doped layer 270 (or buffer layer 275, if present). Anode 280 may be sufficiently transparent to create a top emitting device. Both anode 280 and cathode 220 may be transparent or partially transparent to create a transparent OLED. A hole injection enhancement layer may be used to increase the injection of holes from cathode 180 into n-doped layer 270 (or buffer layer 275, if present).

The blocking properties of first blocking layer 240 and second blocking layer 260 are preferably similar to those of second blocking layer 160 and first blocking layer 140, respectively, of device 1, with respect to holes, electrons, and excitons.

A second preferred embodiment uses the following materials and thicknesses:
substrate 210 commercially available ITO coated (150 nm) substrate
and cathode 220:
n-doped layer 230: 15 nm BPhen:Li (1:1)
first blocking layer 240: 20 nm BPhen
emissive layer 250: 10 nm CBP:Ir(ppy)3 (13:1)
second blocking layer 260: 10 nm Ir(ppz)3
n-doped layer 270: 180 nm m-MTDATA:F4-TCNQ (50:1)
buffer layer 275 20 nm CuPc:F4-TCNQ (50:1)
anode 280: 80 nm ITO

The second preferred embodiment has an energy level diagram similar to that of the first embodiment with respect to the blocking and emissive layers, except that it is inverted. The second preferred embodiment may have a high efficiency and low operating voltage for reasons similar to those described with respect to the first preferred embodiment. Tunneling through thin depletion layers from the electrodes into the transport layers may contribute to the injection of carriers from the electrodes. The relatively thick p-doped layer 270 and buffer layer 275 protect emissive layer 250 from damage during the sputter deposition of anode 280, yet result in low ohmic losses to efficiency due to the doping and resultant high conductivity.

BAlq and BCP may be suitable substitutes for BPhen in any of the embodiments.

It is understood that the various embodiments described herein are by way of example only, and are not intended to limit the scope of the invention. For example, many of the materials described herein may be substituted with other materials without deviating from the spirit of the invention.

Material Definitions:

As used herein, abbreviations refer to materials as follows:
CBP: 4,4′-N,N′-dicarbazole-biphenyl
m-MTDATA 4,4′,4″-tris(3-methylphenylphenlyamino)triphenylamine
Alq3: 8-tris-hydroxyquinoline aluminum
Bphen: 4,7-diphenyl-1,10-phenanthroline
n-BPhen: n-doped BPhen (doped with lithium)
F4-TCNQ: tetrafluoro-tetracyano-quinodimethane
p-MTDATA: p-doped m-MTDATA (doped with F4-TCNQ)
Ir(ppy)3: fac-tris(2-phenylpyridine)-iridium
Ir(ppz)3: fac-tris(1-phenylpyrazoloto,N,C(2′)iridium(III)
BCP: 2,9-dimethyl-4,7-diphenyl-1,10-phenanthroline
TAZ: 3-phenyl-4-(1′-naphthyl)-5-phenyl-1,2,4-triazole
CuPc: copper phthalocyanine.
ITO: indium tin oxide
NPD: naphthyl-phenyl-diamine
TPD: N,N′-bis(3-methylphenyl)-N,N′-bis-(phenyl)-benzidine
BAlq: aluminum(III)bis(2-methyl-8-quinolinato)4-phenylphenolate
   Experimental:

The devices described herein were fabricated using deposition techniques known to the art. The deposition of organic layers was by thermal deposition under a vacuum of at least about 10⁻⁷ torr.

A first device was fabricated having the following layer sequence:
commercially available ITO (indium tin oxide) on a substrate
50 nm m-MTDATA:F4-TCNQ (50:1)
10 nm Ir(ppz)3
5 nm CBP:Ir(ppy)3 (13:1)
40 nm BPhen
20 nm BPhen*Li (1:1)
Al cathode

A second device was fabricated having the same layer sequence as the first device, except the 10 nm Ir(ppz)3 was replaced by 10 nm NPD.

A third device was fabricated having the same layer sequence as the second device, except the thickness of the 5 nm CBP:Ir(ppy)3 (13:1) was increased to 20 nm.

A fourth device was fabricated as described in Adachi, Baldo, Thompson, and Forrest, “High Efficiency Organic Devices With tris(2-phenylpyridine) Iridium Doped Into Electron Transporting Materials,” J. Appl. Phys., 77, 904 (2000).

A fifth device was fabricated as described in Adachi, Baldo, Thompson, and Forrest, “Neary 100% Internal Phosphorescent Efficiency In An Organic Light Emitting Device,” J. Appl. Phys., 90, 5048 (2001).

A sixth device was fabricated having the same layer sequence as the second device, except the thickness of the 40 nm BPhen layer was decreased to 25 nm, and the thickness of the 20 nm BPhen layer was increased to 35 nm.

A seventh device was fabricated having the same layer sequence as the second device, except the thickness of the 40 nm BPhen layer was increased to 60 nm, and the 20 nm BPhen:Li layer was eliminated and replaced with a 1 nm layer of Li.

An eighth device was fabricated having the following layer sequence:
commercially available ITO (indium tin oxide) on a substrate
50 nm NPD
5 nm CBP:Ir(ppy)3 (13:1)
10 nm BCP
40 nm Alq3
LiF:Al cathode

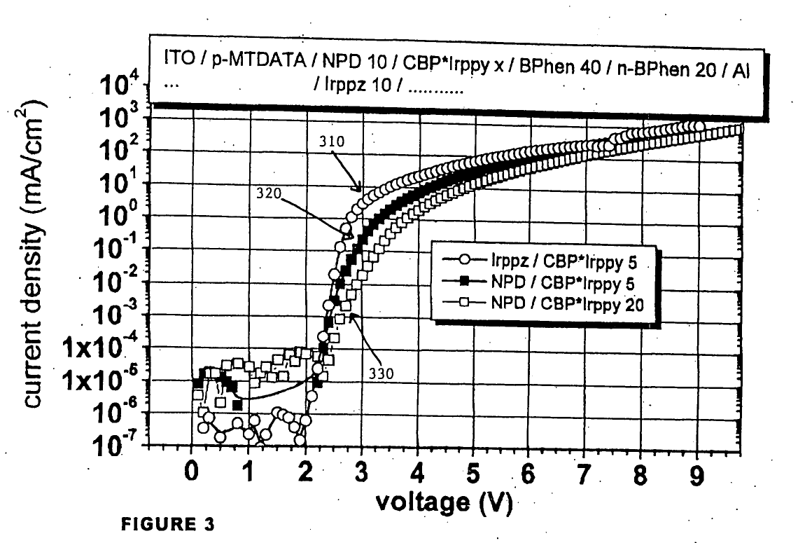

FIG. 3 is a graph depicting the I-V characteristics of device 1, device 2 and device 3. Plot 310 illustrates the current density (mA/cm2) for device 1 plotted against bias voltage (V). Plot 320 illustrates the current density (mA/cm2) for device 2 plotted against bias voltage (V). Plot 330 illustrates the current density (mA/cm2) for device 3 plotted against bias voltage (V). The current density for all devices 1-3 demonstrates a sharp increase between two and three volts, such that the operating voltage is a remarkably low 2-9 volts. Device 1, with an Ir(ppz)3 blocking layer, is able to generate a larger current density at relevant voltages when compared to device 2 and device 3, which has an NPD blocking layer, particularly between three and seven volts.

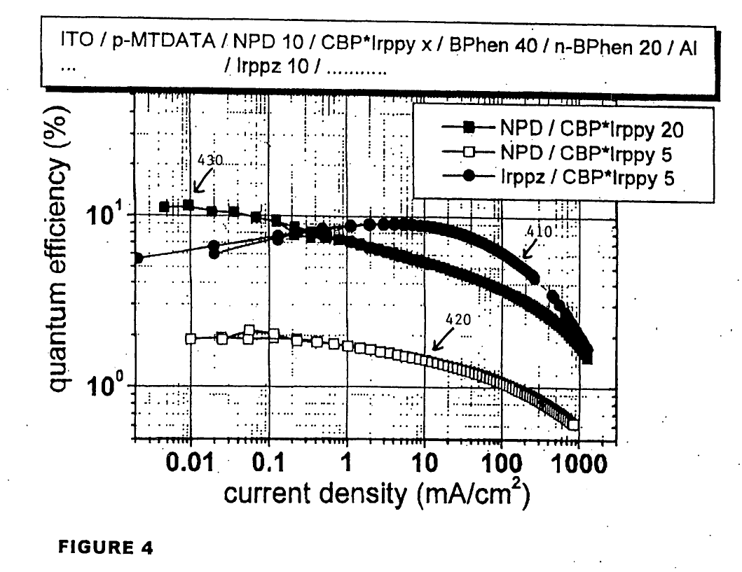

FIG. 4 is a graph depicting the quantum efficiency-voltage characteristics of device 1, device 2 and device 3. Plot 410 illustrates the quantum efficiency (%) for device 1 plotted against current density (mA/cm2). Plot 420 illustrates the quantum efficiency (%) for device 2 plotted against current density (mA/cm2). Plot 430 illustrates the quantum efficiency (%) for device 3 plotted against current density (mA/cm2). Device 1 shows a higher quantum efficiency for current densities above about 0.5 mA/cm2.

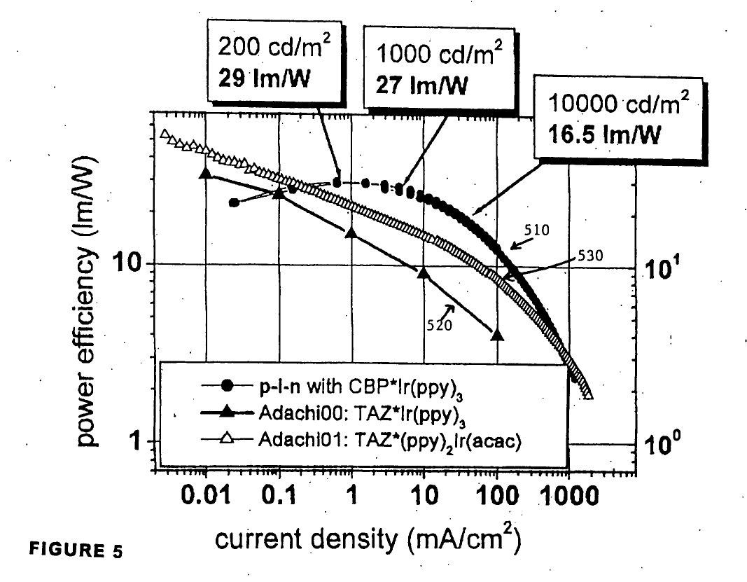

FIG. 5 is a graph depicting the power efficiency-current density characteristics of device 1, device 4 and device 5. Plot 510 illustrates the power efficiency (lumens per watt or lm/W) of device 1 plotted against the current density (mA/cm2). Plot 520 illustrates the power efficiency (lm/W) of device 4 plotted against the current density (mA/cm2). Plot 530 illustrates the power efficiency (lm/W) of device 5 plotted against the current density (mA/cm2). Similar to FIG. 4, device 1 shows a higher power efficiency for current densities above about 0.5 mA/cm2.

FIG. 5 shows that device 1, fabricated in accordance with an embodiment of the present invention, has a power efficiency of 27 lm/W at an intensity of 1000 cd/m². Device 1 has a CBP:Ir(ppy)3 (13:1) emissive layer, which is adapted to emit green light. It is believed that this power efficiency at this intensity, for green light, is greater than any previously attained for an organic light emitting device. It is therefore possible to fabricate organic devices adapted to emit green light having a power efficiency greater than about 20 lm/W at an intensity of 1000 cd/m², which is also believed to be superior to any previously attained results.

As used herein, the term “blue” light refers to an emission spectrum having a peak wavelength less than or equal to about 495 nm, the term “green” light refers to an emission spectrum having a peak wavelength greater than about 495 nm and less than or equal to about 580 nm, and the term “red” light refers to an emission spectrum having a peak wavelength greater than about 580 nm.

It is generally known that blue and red OLEDs have lower power efficiencies than green OLEDs. Based on the results achieved for the green OLED, the structure of device 1 may be adapted to emit either red or blue light having a power efficiency greater than about 7 lm/W at an intensity of about 1000 cd/M² by adjusting the composition of the layers.

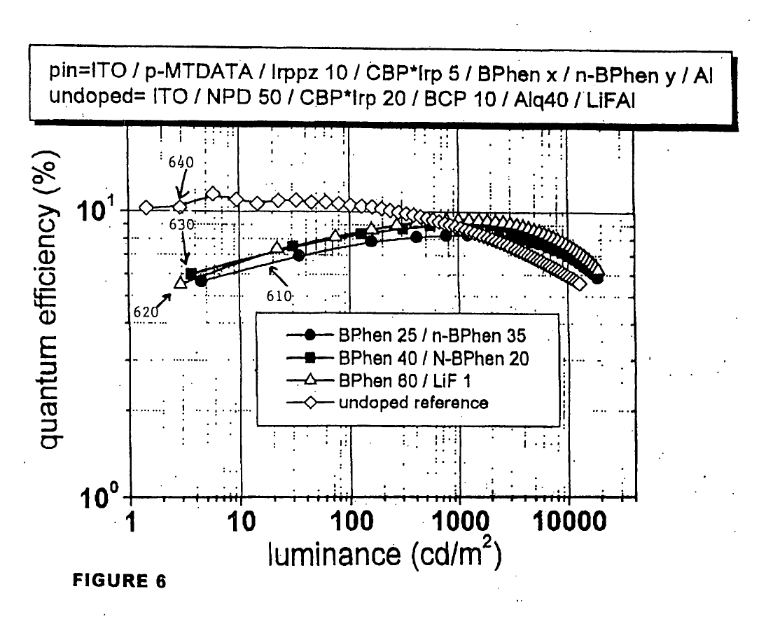

FIG. 6 is a graph depicting the quantum efficiency-luminance characteristics of device 2, device 6, device 7 and device 8. Plot 610 illustrates the quantum efficiency (%) of device 6 plotted against the luminance (cd/m2). Plot 620 illustrates the quantum efficiency (%) of device 7 plotted against the luminance (cd/m2). Plot 630 illustrates the quantum efficiency (%) of device 2 plotted against the luminance (cd/m2). Plot 640 illustrates the quantum efficiency (%) of device 8 plotted against the luminance (cd/m2). FIG. 6 shows that devices fabricated in accordance with embodiments of the invention have a relatively high quantum efficiency at a high luminance. High quantum efficiency at high luminance is a desirable characteristic for display devices and light sources.

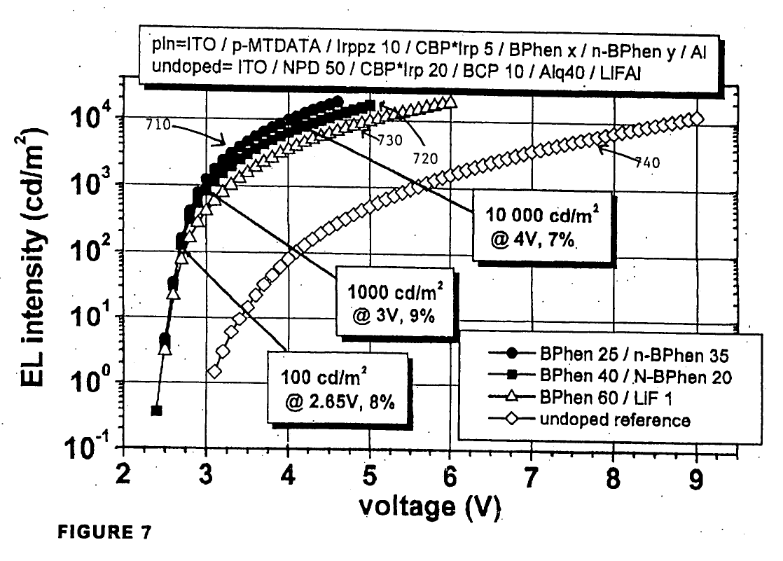

FIG. 7 is a graph depicting the electroluminescent (EL) intensity-voltage characteristics of device 2, device 6, device 7 and device 8. Plot 710 illustrates the EL intensity (cd/m2) of device 6 plotted against the voltage (V). Plot 720 illustrates the EL intensity (cd/m2) of device 2 plotted against the voltage (V). Plot 730 illustrates the EL intensity (cd/m2) of device 7 plotted against the voltage (V). Plot 740 illustrates the EL intensity (cd/m2) of device 8 plotted against the voltage (V). FIG. 7 shows that devices fabricated in accordance with embodiments of the invention show a dramatic rise in emission between about 2.5 and 3.5 volts. Such devices reach an intensity of 1000 cd/m2 at about 3 V, with 9% quantum efficiency, and an intensity of about 10,000 cd/m2 at about 4 V, with about 7% quantum efficiency. These are desirably high intensities at low voltages.

Inverted Devices

A ninth device was fabricated having the following layer sequence:
commercially available ITO on a substrate
3 nm Alq3
15 nm n-BPhen
20 nm BPhen
10 nm CBP:Ir(ppy)3
10 nm r(ppz)3
180 nm p-MTDATA
20 nm p-CuPc
ITO

A tenth device was fabricated having the same layer sequence as the ninth device, but omitting the 3 nm Alq3.

An eleventh device was fabricated having the same layer sequence as the tenth device, but omitting the top ITO layer. Because it does not have a top electrode, the eleventh device is not a functional device, but is useful for characterizing light transmission properties.

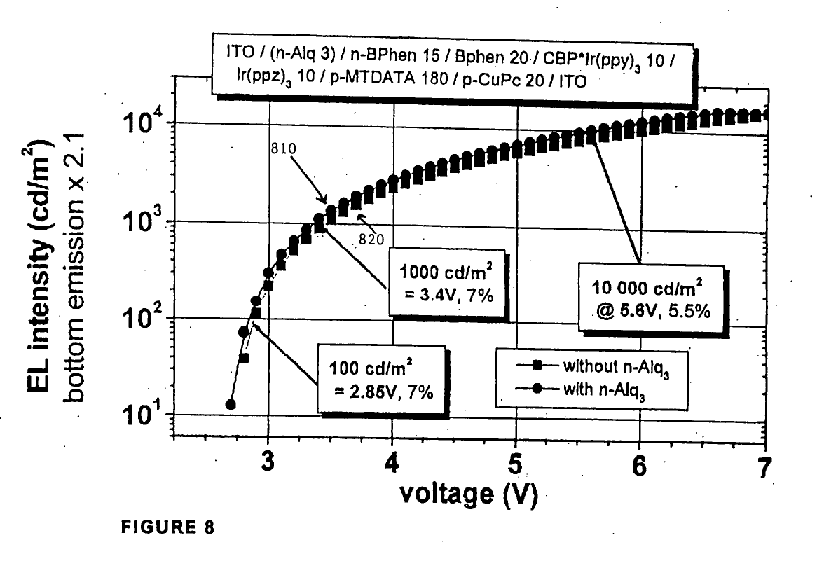

FIG. 8 is a graph depicting the EL intensity-voltage characteristics for device 9 and device 10, with light intensity measured through the bottom electrode. Plot 810 illustrates the EL intensity (cd/m2) of device 9 plotted against the voltage (V). Plot 820 illustrates the EL intensity (cd/m2) of device 10 plotted against the voltage (V). Typically, conventional inverted devices have an operating voltage of 20 volts. Remarkably, as this graph illustrates, the operating voltage for inverted devices 9 and 10, in accordance with embodiments of the present invention, ranges between 2.5 and 7 volts, which is substantially less than that of conventional inverted devices using intrinsic transport layers.

FIG. 8 shows that the drive voltage of device 10 is 2.85 V at 100 cd/m², 3.4 V at 1000 cd/m², and 5.6 V at 10000 cd/m². One factor that contributes to drive voltage is the energy of photons emitted by the emissive layer (the “photon energy”), which is about 2.4 eV for the CBP:Ir(ppy)3 emissive layer of devices 9 and 10. All of the other factors that contribute to drive voltage result in an addition to the photon energy. For device 10, this additional voltage is 0.45 V at 100 cd/m², 1 V at 1000 cd/M², and 3.2 V at 10000 cd/m². These additions should be consistent for devices having different photon energies. The present invention may therefore be used to fabricate n-i-p devices having a drive voltage at 100 cd/m² that is not more than about 1.5 volts higher than the photon energy of the emissive layer. N-i-p devices having a drive voltage at 1,000 cd/M² that is not more than about 2 volts higher than the photon energy of the emissive layer may also be fabricated. N-i-p devices having a drive voltage at 10,000 cd/m² that is not more than about 4 volts higher than the photon energy of the emissive layer may also be fabricated.

It is possible to fabricate a phosphorescent OLED adapted to emit white light by adding one or more components to the emissive layer of devices 9 or 10. Generally, white emitting devices have a drive voltage that is similar to that for green emitting devices, but slightly higher. Based on the measurements reported in FIG. 8 for devices 9 and 10, such a device would have a drive voltage of not greater than about 4 V at 100 cd/m², not greater than about 4.5 V at 1000 cd/m², and not greater than about 6.5 V at 10000 cd/m².

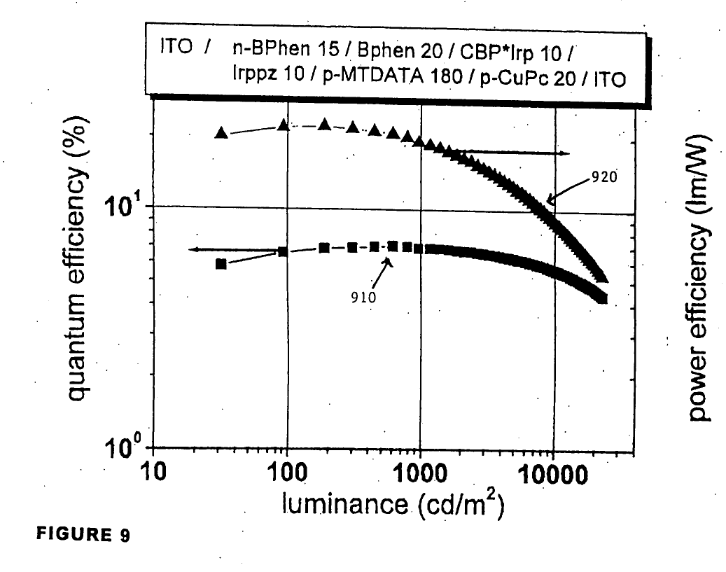

FIG. 9 is a graph shows the quantum efficiency and the power efficiency of device 10. Plot 910 illustrates the quantum efficiency (%) of device 10 plotted against the luminance (cd/m2). Plot 920 illustrates the power efficiency (%) of device 10 plotted against the luminance (cd/m2) for the same device.

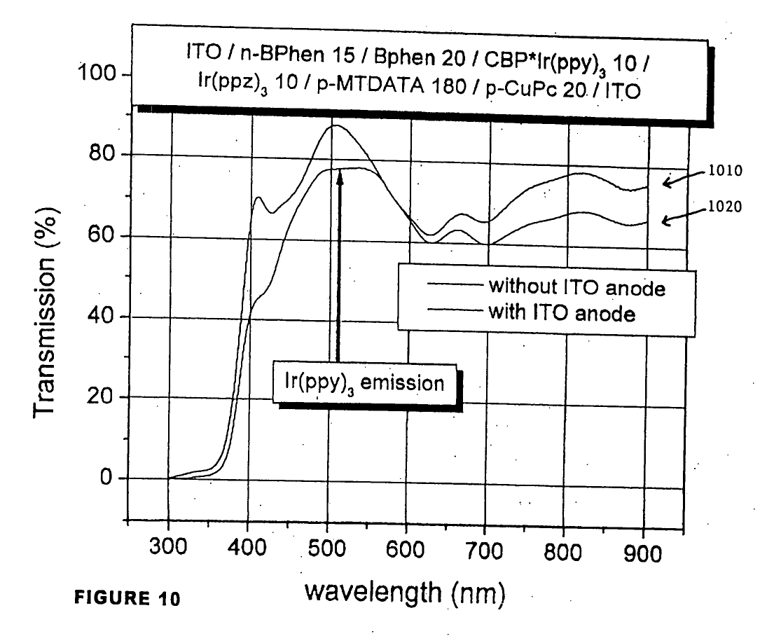

FIG. 10 is a graph depicting the transmission-wavelength characteristics for device 10 and device 11. Plot 1010 illustrates the transmission (%) of device 11 plotted against the wavelength (nm). Plot 1020 illustrates the transmission (%) of device 10 plotted against the wavelength (nm). As is illustrated in FIG. 10, the inverted device 10 has sufficient transparency in the visible range for practical purposes.

1. An organic light emitting device, comprising:
(a) an anode disposed over a substrate;
(b) a p-doped organic layer disposed over and electrically connected to the anode;
(c) a phosphorescent organic emissive layer disposed over and electrically connected to the p-doped organic layer;
(d) an n-doped organic layer disposed over and electrically connected to the phosphorescent organic emissive layer;
(e) a cathode disposed over and electrically connected to the n-doped organic layer; and at least one of
(f) a first blocking layer disposed between and electrically connected to the p-doped organic layer and the emissive layer, the first blocking layer adapted to block electrons and excitons from entering the p-doped organic layer; and
(g) a second blocking layer disposed between and electrically connected to the n-doped organic layer and the emissive layer, the second blocking layer adapted to block holes and excitons from entering the n-doped layer.

2. The organic light emitting device of claim 1, wherein the first and/or the second blocking layers arc layer is not doped.

3. The organic light emitting device of claim 1, wherein the emissive layer is an intrinsic semiconductor.

4. The organic light emitting device of claim 1, wherein:
when present, the first blocking layer comprises Ir(ppz)3;
the emissive layer comprises CBP:Ir(ppy)₃ (13:1); and
when present, the second blocking layer comprises BPhen.

5. The organic light emitting device of claim 1, comprising:
the first blocking layer disposed between and electrically connected to the p-doped organic layer and the emissive layer.

6. The organic light emitting device of claim 5, wherein the first blocking layer is not doped.

7. The organic light emitting device of claim 1, comprising:
the second blocking layer disposed between and electrically connected to the n-doped organic layer and the emissive layer.

8. The organic light emitting device of claim 7, wherein the second blocking layer is not doped.

9. The organic light emitting device of claim 1,
wherein the first blocking layer is present, and is adapted to inject electrons into the emissive layer and to block holes and excitons from entering the first blocking layer; and/or
the second blocking layer is present, and is adapted to inject holes into the emissive layer and to block electrons and excitons from entering the second blocking layer.

10. The organic light emitting device of claim 9, wherein the first and/or the second blocking layer is not doped.

11. The organic light emitting device of claim 9, wherein:
when present, the first blocking layer comprises Ir(ppz)₃;
the emissive layer comprises CBP:Ir(ppy)₃ (13:1); and
when present, the second blocking layer comprises BPhen.

12-22. (canceled)

23. An The organic light emitting device of claim 1, comprising:
wherein the p-doped layer comprises m-MTDATA:F4-TCNQ (50:1);
when present, the first blocking layer comprises Ir(ppz)₃;
the emissive layer comprises CBP:Ir(ppy)₃ (13:1);
when present, the second blocking layer comprises BPhen; and
the n-doped layer comprises BPhen*Li (1:1).

24. The organic light emitting device of claim 23, wherein:
(a) a thickness of the first blocking layer is at most about 100 Angstroms;
(b) a thickness of the emissive layer is at most about 50 Angstroms; and
(c) a thickness of the second blocking layer is at most about 250 Angstroms.

25. (canceled)

26. (canceled)

27. The organic light emitting device of claim 1, made by the process of:
(a) providing an anode on a substrate;
(b) depositing a layer of m-MTDATA:F4-TCNQ (50:1) over the anode;
(c) optionally, depositing a layer of Ir(ppz)₃ over the layer of m-MTDATA:F4-TCNQ (50:1);
(d) depositing a layer of CBP:Ir(ppy)₃ (13:1) over the layer of Ir(ppz)₃;
(e) optionally, depositing a layer of BPhen over the layer of CBP:Ir(ppy)₃;
(f) depositing a layer of BPhen*Li (1:1) over the layer of BPhen; and
(g) depositing a cathode over the layer of BPhen*Li (1:1); wherein at least one of the Ir(ppz)₃ layer and the BPhen layer is deposited.

28. The organic light emitting device of claim 27, wherein:
(a) the layer of Ir(ppz)₃ is deposited to a thickness of at most about 100 Angstroms;
(b) the layer of CBP:Ir(ppy)₃ (13:1) is deposited to a thickness of at most about 50 Angstroms; and
(c) the layer of BPhen is deposited to a thickness of at most about 250 Angstroms.

29-35. (canceled)

36. The organic light emitting device of claim 1, wherein the phosphorescent emissive layer is adapted to emit light having a peak wavelength less than or equal to about 495 nm, and wherein the power efficiency of the device is greater than about 7 lumens per watt at an intensity of about 1000 cd/M².

37. The organic light emitting device of claim 1, wherein the phosphorescent emissive layer is adapted to emit light having a peak wavelength greater than about 495 nm and less than or equal to about 580 nm, and wherein the power efficiency of the device is greater than about 20 lumens per watt at an intensity of about 1000 cd/m².

38. The organic light emitting device of claim 1, wherein the phosphorescent emissive layer is adapted to emit light having a peak wavelength greater than about 580 nm, and wherein the power efficiency of the device is greater than about 7 lumens per watt at an intensity of about 1000 cd/m².

39. The organic light emitting device of claim 1, adapted to emit substantially white light having an intensity of at least about 100 cd/m² at a drive voltage of not greater than about 4 volts.

40. The organic light emitting device of claim 1, adapted to emit substantially white light having an intensity of at least about 1,000 cd/m² at a drive voltage of not greater than about 4.5 volts.

41. The organic light emitting device of claim 1, adapted to emit substantially white light having an intensity of at least about 100 cd/m² at a drive voltage of not greater than about 6.5 volts.

42. The organic light emitting device of claim 1, comprising the first blocking layer disposed between and electrically connected to the p-doped organic layer and the emissive layer and the second blocking layer disposed between and electrically connected to the n-doped organic layer and the emissive layer.

43. The organic light emitting device of claim 42, wherein the first and second blocking layers are not doped.
